(19) United States
(12) Patent Application Publication
(10) Pub. No.: US 2013/0168340 A1
(43) Pub. Date: Jul. 4, 2013

(54) PROFILED SUPPORT ELEMENT OF A ROW OF PV MODULES

(71) Applicant: Hans Urban, Haag (DE)

(72) Inventor: Hans Urban, Haag (DE)

(73) Assignee: Schletter GmbH, Kirchdorf (DE)

(21) Appl. No.: 13/702,586

(22) PCT Filed: Jun. 9, 2011
(86) PCT No.: PCT/DE2011/001337

§ 371 Date: Feb. 19, 2013

(30) Foreign Application Priority Data
Jun. 9, 2010 (DE) 102010023212.2

(51) Int. Cl. H01L 31/042

(52) U.S. Cl. CPC H01L 31/0422
USPC 211/41.1; 29/428

(57) ABSTRACT

A support rail for a row of PV modules includes an outer hollow rail, a first inner hollow rail comprising a metal, and an insulating device configured to electrically separate the outer hollow rail from the first inner hollow rail. The first inner hollow rail is accommodated within the outer hollow rail via the insulating device and is held in all directions transversely to the support rail in a positive-locking manner within the outer hollow rail by the insulating device.

### CROSS REFERENCE TO PRIOR APPLICATIONS

This application is a U.S. National Phase application under 35 U.S.C. §371 of International Application No. PCT/DE2011/001337, filed on Jun. 9, 2011 and which claims benefit to German Patent Application No. 10 2010 023 212.2, filed on Jun. 9, 2010. The International Application was published in German on Apr. 5, 2012 as WO 2012/041266 A1 under PCT Article 21(2).

### FIELD

The present invention relates to a support rail of a row of PV modules.

### BACKGROUND

Such a support rail supports several photovoltaic modules, shortly named PV modules, ordered in a row. In practice for this purpose, the support rail is an element in a support structure arranged on a roof or on open field. The support rail can comprise an electric conductor especially useful for the transmission of direct current to an inverter.

WO 2004/017424 A2 describes a fixing device for PV modules. The fixing device comprises hollow profiled rails in which current lines with comparably small cross sections are mounted underneath a bearing surface of the profiled rails.

DE 20 2006 012 495 U1 describes a support rail for a row of PV modules which has no electric conductor.

### SUMMARY

An aspect of the present invention is to provide a material-efficient support rail for bearing a row of PV modules, wherein the support rail comprises an integrated electric conductor. An additional aspect of the present invention is to provide an electric conductor which has a large material cross section but which does not lower the bearing capacity of the support rail due to its own weight.

In an embodiment, the present invention provides a support rail for a row of PV modules which includes an outer hollow rail, a first inner hollow rail comprising a metal, and an insulating device configured to electrically separate the outer hollow rail from the first inner hollow rail. The first inner hollow rail is accommodated within the outer hollow rail via the insulating device and is held in all directions transversely to the support rail in a positive-locking manner within the outer hollow rail by the insulating device.

### BRIEF DESCRIPTION OF THE DRAWINGS

The present invention is described in greater detail below on the basis of embodiments and of the drawings in which:

FIG. 1 shows a schematic plan view of a support rail of a row of several PV modules;

FIG. 2 shows a lateral view of the support rail according to FIG. 1;

FIG. 3 shows separate lateral views of an outer hollow rail, an insulating means, and an inner hollow rail of the support rail according to FIG. 1;

FIG. 4 shows a lateral view of a further support rail;

FIG. 5 shows a lateral view of a further support rail;

FIG. 6 shows a lateral view of a further support rail; and

FIG. 7 shows a schematic circuit topology with the support rail according to FIG. 1.

### DETAILED DESCRIPTION

In an embodiment of the present invention, the inner hollow rail can be used as an insulated electric conductor for alternating and/or direct current, and can in particular be provided in a bending resistant manner due to its hollow cross section. In addition, as the inner hollow rail is held in all transverse directions within the outer hollow rail in a positive-locking manner, the bearing characteristics of the outer hollow rail and of the inner hollow rail complement each other in an advantageous manner. The material cross section of the inner hollow rail can thus be designed to be very large, which is both electrically and structurally advantageous. The outer hollow rail may thus be embodied with less load-bearing capacity than the profiled rails known from prior art. Due to the form-fit holding, the inner hollow rail is not able to move within the outer hollow rail in any direction transversely to the support rail. It should be understood that suitable form tolerances, in particular clearance fits, may be present, wherein undersize fits are possible as well.

In an embodiment of the present invention, the length of the support rail can, for example, be between 4 and 20 meters in order to be able to bear a plurality of PV modules in a row. The outer hollow rail and the inner hollow rail may have substantially the same length. For the purpose of mechanical and electric connection, it may be of advantage if the inner hollow rail marginally, with respect to the entire length, sets back and/or projects at the ends of the outer hollow rail. The degree of such a setback or projection can, for example, be less than 10 cm or less than 2% of the entire support rail length.

The outer hollow rail may be made of metal like the inner hollow rail. Both hollow rails can, for example, consist of a corrosion resistant, lightweight and well conducting aluminum. Alternatively or additionally, it is possible that the outer hollow rail consists of plastic material and/or wood.

For a high load-bearing capacity of the support rail, it is practical that the outer and/or the inner hollow rail each have a closed hollow cross section. Both the outer and the inner hollow rail can, for example, be made of one single cell, in other words, they are provided with exactly one single hollow chamber. It is also possible, however, to design them in multi-cell form.

The inner cross section of the outer hollow rail and/or the outer cross section of the inner hollow rail may advantageously each be designed polygonally. This may further increase the load-bearing capacity of the support rail. In an embodiment of the present invention, the inner cross section of the outer hollow rail and the outer cross section of the inner hollow rail can, for example, be provided so as to be substantially congruently equal. The reception and the form-fit holding of the inner hollow rail within the outer hollow rail by means of the insulating means can thus be obtained in a particularly material-efficient manner. For the same reason, it may be possible that the inner cross section of the outer hollow rail and an envelope polygon of the outer cross section of the inner hollow rail are substantially congruently equal.

In an embodiment of the present invention, the inner hollow rail can, for example, be arranged centrally within the outer hollow rail, particularly in combination with the above-described congruency of the shapes.

In an embodiment of the present invention, the ratio between the area of the inner cross section of the inner hollow rail and the area of the inner cross section of the outer hollow rail can, for example, be larger than 0.4 and less than 1. The ratio between the section modulus of the inner hollow rail and the section modulus of the outer hollow rail is, in each direction transversely to the support rail, for example, larger than 0.1 and less than 0.5. These quotients, in particularly in combination, have proved advantageous regarding the load-bearing capacity and the material utilization.

For effecting the reception and the form-fit holding in all transverse directions, the insulating material can have, in a peripheral direction, at least sectionally, a fitting counter-form to the outer hollow rail and a fitting counter-form to the inner hollow rail.

In an embodiment of the present invention, the insulating means can, for example, be provided in multi-parts longitudinally and/or transversely to the support rail. This can be material-saving. Practical distances in the longitudinal direction between such parts may particularly be ranged between 20 and 50 cm. In case of a multi-part embodiment in the transverse direction, the parts of the insulating means can, for example, be arranged at several outer edges of the inner hollow rail, for example, at the four outer external corners of a trapezoidal form.

In an embodiment of the present invention, the insulating means can, for example, have a hollow profile, in particular, a closed hollow profile. The insulating means may additionally have substantially the same length as the outer and the inner hollow rail. Such an insulating means is easy to join, and circumferentially separates the outer hollow rail and the inner hollow rail from each other electrically. It is also possible to provide the insulating means in form of several longitudinally arranged hollow profiled parts. In this way, the support rail can be constructed with three shells—either sectionally or, for example, substantially over its entire length.

In an embodiment of the present invention, the outer hollow rail and/or the inner hollow rail and/or the insulating means can, for example, each have an extrudable basic shape. Manufacturing by means of extrusion is thus possible.

Several spacing elements may be disposed at the outer side and/or at the inner side of the insulating means. Such spacing elements may facilitate joining and allow larger tolerances during manufacturing the inner and/or the outer hollow rail and/or the insulating means. This especially applies for an insulating means embodied in form of a longitudinal continuously running hollow rail.

For fastening the supported PV modules or for fastening the support rail to a substructure, it is advantageous if the outer hollow rail comprises at least one undercut fastening channel on its outer side. Such a fastening channel can, for example, be undercut on both sides and can, for example, be engaged from behind by means of nut bolts.

For fastening the supported PV modules, the outer hollow rail may, for example, have a plane bearing surface and an undercut fastening channel at its outer side, wherein the fastening channel optionally divides the bearing surface, and the PV modules rest on the bearing surface.

For fastening the support rail, the outer hollow rail can, for example, comprise fastening edges or fastening grooves at its outer side at which the outer hollow rail can be or is fastened to a substructure. Such a type of fastening is practical, multifunctional and safe.

In an embodiment of the present invention, the bearing surface and the fastening edges and/or the fastening grooves can, for example, be provided on opposing sides of the outer hollow rail. The fastening edges may in particular be arranged on the side facing the substructure, and the bearing surfaces may be arranged on the side facing the PV modules.

The outer hollow rail, the inner hollow rail and the insulating means may of course have many different profile shapes. Thus, rectangular, squared, cylindrical, elliptical as well as any polygonal, particularly triangular and hexagonal, shapes can be used. In an embodiment of the design of the support rail, it can, for example, be provided that the inner cross section of the outer hollow rail and/or the outer cross section of the inner hollow rail and/or the outer cross section of the insulating means and/or the inner cross section of the insulating means are trapezoidal. The trapezoidal shape turned out to be structurally advantageous. For the same reason, a four-sided envelope polygon of the outer cross section of the outer hollow rail and/or the outer cross section of the insulating means and/or the outer cross section of the inner hollow rail can each, for example, form a trapezoid. It is additionally possible that the cross section of the outer hollow rail is based on a trapezoidal shape, one parallel side of the trapezoidal form is extended on both sides by means of two fastening edges, and on the other side of the trapezoidal form a bearing chord is arranged by means of an undercut fastening channel.

In an embodiment of the present invention, the outer hollow rail may, for example, comprise at least one three-sided reception channel into which the PV modules are on one side thereof inserted with their edges or frames. In an embodiment of the present invention, the outer hollow rail may comprise exactly two such three-sided reception channels that are opened in opposite directions such that two rows of PV modules can be inserted with their edges or frames, each on one side thereof respectively.

In a variation thereof, beside the inner hollow rail, a second metallic inner hollow rail is provided, wherein the insulating means also separates the outer hollow rail and the second inner hollow rail from each other electrically, and the second inner hollow rail is also accommodated within the outer hollow rail by means of the insulating means, and is also held in all directions transversely to the support rail in a positive-locking manner within the outer hollow rail by means of the insulating means. In a further variation, a second metallic inner hollow rail and a second insulating means may be provided, wherein the second insulating means separates the first inner hollow rail and the second inner hollow rail from each other electrically, and the second inner hollow rail is accommodated within the first inner hollow rail by means of the second insulating means and is held in all directions transversely to the support rail in a positive-locking manner within the first inner hollow rail by means of the second insulating means. In these variants, there advantageously can be used two insulated conductors, particularly as a substitute for a two-wire direct current cable.

For manufacturing the support rail according to the present invention, at first the insulating means may be arranged on the outer side of the inner hollow rail, and then the inner hollow rail together with the insulating means may be inserted into the outer hollow rail. In a variant, at first, the insulating means may be arranged on the inner side of the outer hollow rail, and then the inner hollow rail may be inserted into the insulating means. Arranging the insulating means may, for example, be performed by spraying, wrapping, pushing, pulling, gluing or co-extruding. Inserting the inner hollow rail is optionally done together with the insulating means, for example, in slide-in, push-in or press-in manner. It is also possible to co-extrude the outer hollow rail, the insulating means and the inner hollow rail together in a three-shell string.

In an advantageous electric connection of the support rail, it is provided that the PV modules are integrated in a string of PV modules electrically connected in series, wherein the string is at its one electric end electrically connected with a longitudinal end of the inner hollow rail. The string may additionally be connected electrically at its other electric end with an inverter. The other longitudinal end of the inner hollow rail may be electrically connected with a, for example, the same, inverter.

In an embodiment of the present invention, the string can, for example, be electrically connected at its other electric end with one pole of an inverter, and the other longitudinal end of the inner hollow rail can, for example, be electrically connected with the other pole of the inverter. In this way, a PV generator is created, wherein a part of the direct current wiring is advantageously substituted by the inner hollow rail.

Such a string or the single PV modules may not only be connected with the longitudinal ends of the inner hollow rail but also with connection outlets on arbitrary positions along the support rail. Such a connection outlet may penetrate the outer hollow rail and the insulating means from outside through an opening such that the connection to the inner hollow rail in a direction transversely to the support rail is held free.

For the safety of persons and the PV modules, it is useful to connect the outer hollow rail electrically with a mass or ground potential, and in particular with the earth potential.

The present invention will hereinafter be described in more detail with respect to several embodiments.

FIG. 1 shows a support rail 2 of a row of six PV modules 1, wherein the PV modules 1 are supported on one side by means of the support rail 2. On their other side, the PV modules 1 are supported by a conventional support rail 27.

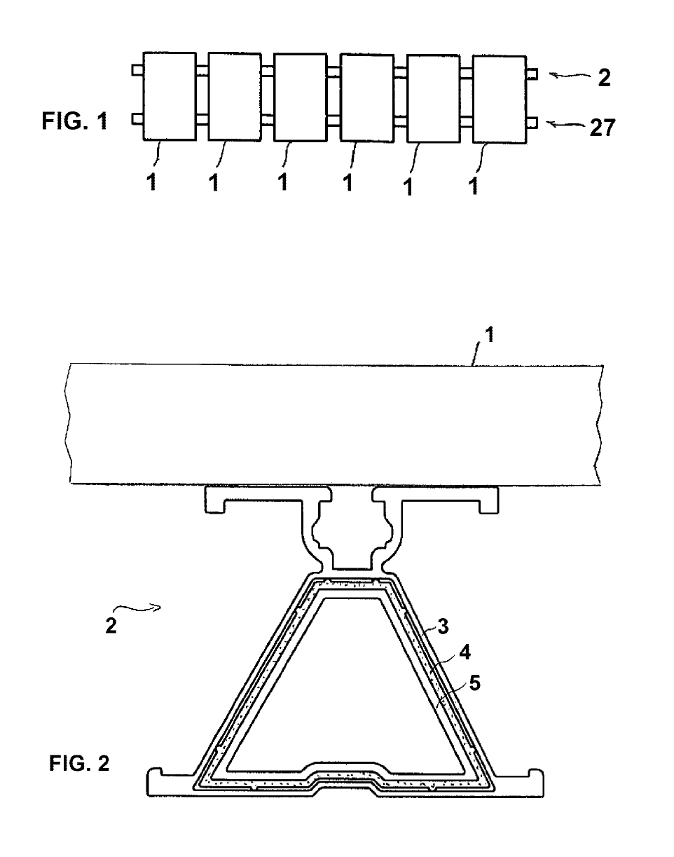

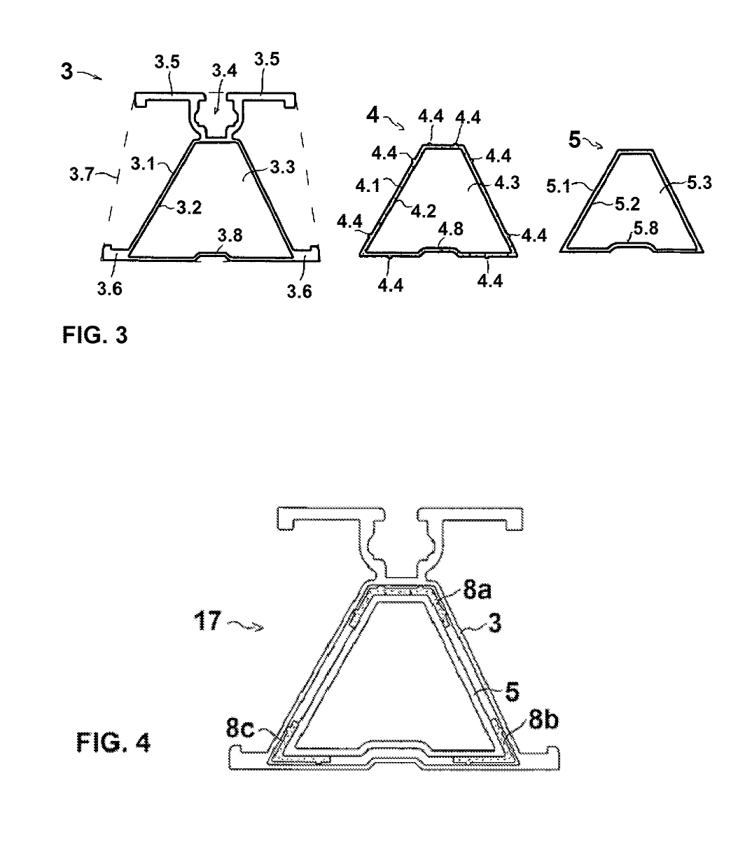

As can particularly be seen in FIG. 2 and FIG. 3, the support rail 2 comprises a metallic outer hollow rail 3, an insulating means 4 and a metallic inner hollow rail 5, wherein the insulating means 4 separates the outer hollow rail 3 and the inner hollow rail 5 from each other electrically. It can additionally be seen that the inner hollow rail 5 is accommodated within the outer hollow rail 3 by means of the insulating means 4, and is held in all directions transversely to the support rail 2 in a positive-locking manner within the outer hollow rail 3 by means of the insulating means 4.

It can furthermore be seen that the inner cross section 3.2 of the outer hollow rail 3 and the outer cross section 5.1 of the inner hollow rail 5 are congruently equal. The inner hollow rail 5 is arranged centrally within the outer hollow rail 3.

The ratio between the inner area 5.3 of the inner cross section 5.2 of the inner hollow rail 5 and the inner area 3.3 of the inner cross section 3.2 of the outer hollow rail 3 is about 0.6. The ratio between the section modulus of the inner hollow rail 5 and the section modulus of the outer hollow rail 3 is in each direction transversely to the support rail 2 larger than 0.2 and less than 0.4.

The outer hollow rail 3 and the inner hollow rail 5 as well as the insulating means 4 that is also embodied in form of a hollow rail each comprise a closed one-cell hollow cross section. They additionally each have an extrudable shape and are about the same length.

The insulating means 4 forms a counter-form to the outer hollow rail 3 and also a counter-form to the inner hollow rail 5. It additionally has several spacing elements 4.4 at its outer side, the spacing elements 4.4 abutting against the outer hollow rail 3 at the inner side thereof.

For inserting the inner hollow rail 5 into the outer hollow rail 3, it is provided that the insulating means 4 is arranged on the outer side of the inner hollow rail 5 at first, and then, the inner hollow rail 5 together with the insulating means 4 is inserted suitably in a positive-locking manner into the outer hollow rail 3.

The outer hollow rail 3 comprises a bearing surface 3.5 and an undercut fastening channel 3.4 on its top side, wherein the fastening channel 3.4 divides the bearing surface 3.5, and the PV modules 1, one of which is shown merely sectionally in FIG. 2, rest on the bearing surface 3.5. The outer hollow rail 3 furthermore comprises two fastening edges 3.6 at its outer lower side, with which the outer hollow rail 3 may be fastened to a conventional substructure that is not shown in detail.

As can be further seen from FIG. 2 and in FIG. 3, the inner cross section 3.2 of the outer hollow rail 3 and the outer cross section 5.1 of the inner hollow rail 5 are substantially trapezoidal. The inner cross section 4.2 and the outer cross section 4.1 of the insulating means 4 are also substantially trapezoidal. Only a stiffening rib 3.8, 4.8 and 5.8 that is provided in all three hollow rails 3, 4 and 5 at the respective lower sides thereof as well as the spacing elements 4.4 at the outer side of the insulating means 4 deviate from a strict trapezoidal form.

Additionally, a four-sided envelope polygon 3.7 of the outer cross section 3.1 of the outer hollow rail 3 that is illustrated by means of a dashed line forms a trapezoid. This also applies for the outer cross section 4.1 of the insulating means 4 and the outer cross section 5.1 of the inner hollow rail 5 which is, however, not shown in detail herein.

The outer cross section 3.1 of the outer hollow rail 3 is based on a trapezoidal form, the upper parallel side of the trapezoidal form is on both sides extended by means of the two fastening edges 3.6, and on the other lower parallel side of the trapezoidal form the bearing surface 3.5 is arranged by means of the walls of the undercut fastening channel 3.4.

With respect to the outer and the inner hollow rail 3 and 5 according to FIG. 3, FIG. 4 shows that the insulating means may alternatively be constructed in multi-parts. Thus, in this embodiment, there are provided three parts 8 a, 8 b and 8 c that may run continuously in the longitudinal direction or may be embodied in multi-parts in the longitudinal direction too. Also in this embodiment, according to the present invention, the inner hollow rail 5 is accommodated within the outer hollow rail 3 and is held in all directions transversely to the support rail 17 within the outer hollow rail 3 in a positive-locking manner by means of the insulating means, to be more precise, by means of its three parts 8 a, 8 b and 8 c.

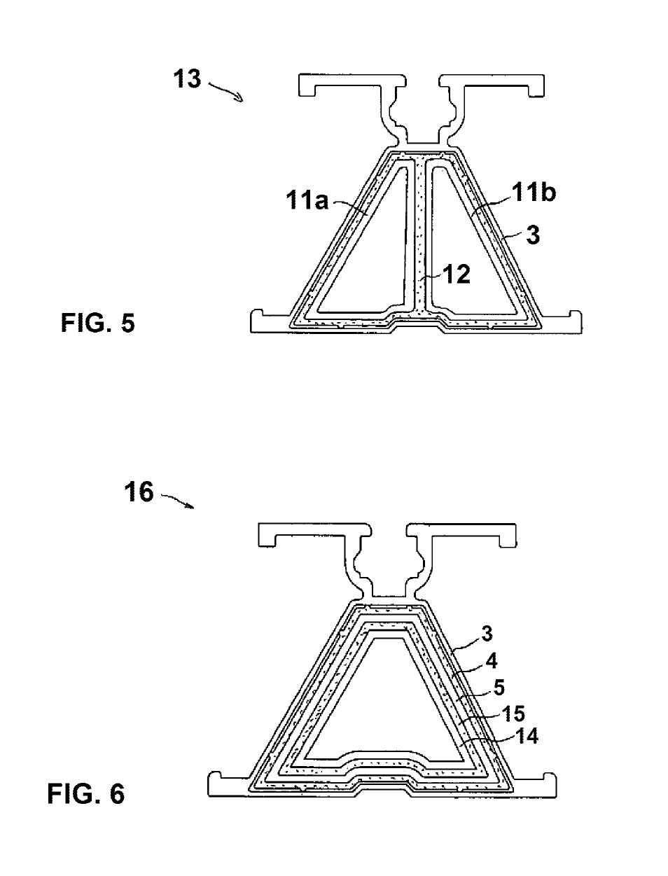

FIG. 5 shows an alternative embodiment of a support rail 13 in which, in addition to the first inner hollow rail 11 a, a second metallic inner hollow rail 11 b is arranged. It is furthermore provided that the insulating means 12 separates the outer hollow rail 3 and the second inner hollow rail 11 b from each other electrically, and the second inner hollow rail 11 b is accommodated within the outer hollow rail 3 by means of the insulating means 12, and is held in all directions transversely to the support rail 13 in a positive-locking manner within the outer hollow rail 3 by means of the insulating means 12. The two inner hollow rails 11 a and 11 b can advantageously be used as a two-core electric conductor.

FIG. 6 shows an alternative embodiment of a support rail 16 in which a second metallic inner hollow rail 14 and a second insulating means 15 are provided, wherein the second insulating means 15 separates the first inner hollow rail 5 and the second inner hollow rail 14 from each other electrically. The second inner hollow rail 14 is accommodated within the first inner hollow rail 5 by means of the second insulating means 15, and is held in all directions transversely to the support rail 16 in a positive-locking manner by means of the second insulating means 15. Also, these two inner hollow rails 5 and 14 can advantageously be used as a two-core electric conductor.

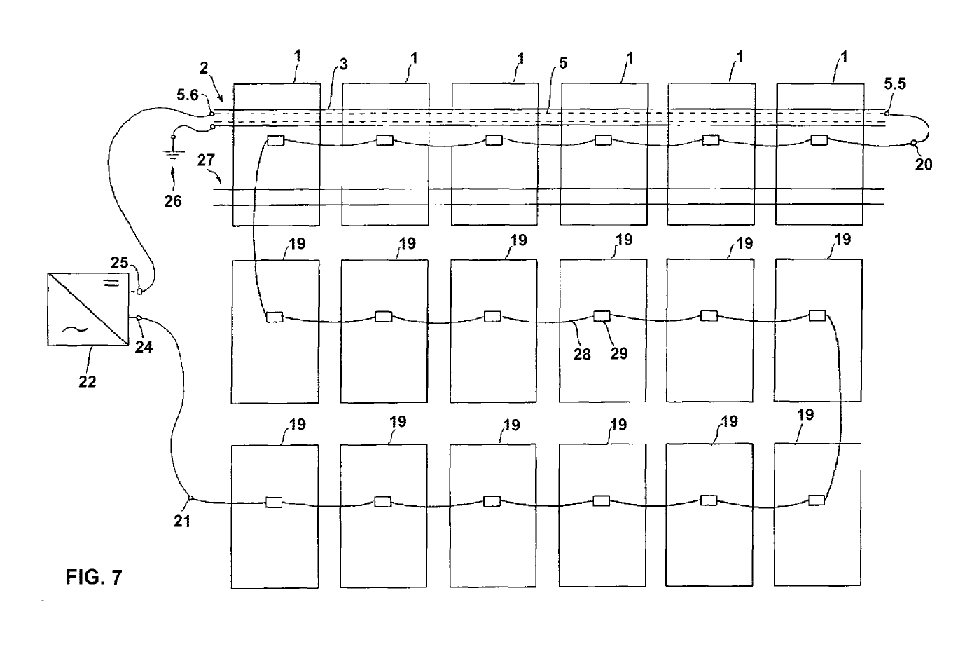

FIG. 7 shows a circuit topology with the support rail according to FIG. 1 and FIG. 3, respectively. The six PV modules 1 are arranged on the support rails 2 and 27. In addition, twelve more PV modules 19 are arranged. And an inverter 22 having a first connection pole 24 and a second connection pole 25 is arranged.

The PV modules 1 and 19 are connected electrically in series within in a string. The string extends from a first electric end 20 to a second electric end 21. Substantially, the string is electrically connected at the first electric end 20 with a first longitudinal end 5.5 of the inner hollow rail 5 and at the second electrical end 21 with the first connection pole 24 to the inverter 22 by means of a connection line. For closing the direct current circuit, the second longitudinal end 5.6 of the inner hollow rail 5 is electrically connected with the second connection pole 25 of the inverter 22 by means of a connection line. It is finally provided that the inner hollow rail 3 is electrically connected with a mass or ground potential 26, in particular, the earth potential.

### REFERENCE NUMERALS

1 PV module
1′ PV module
2 support rail
3 outer hollow rail
3.1 outer cross section
3.2 inner cross section
3.3 inner area
3.4 fastening channel
3.5 bearing surface
3.6 fastening edge
3.7 four-sided envelope polygon
3.8 stiffening rib
4 insulating means
4.1 outer cross section
4.2 inner cross section
4.3 inner area
4.4 spacing elements
4.8 stiffening rib
5 inner hollow rail
5.1 outer cross section
5.2 inner cross section
5.3 inner area
5.4 outer edge
5.5 first longitudinal end
5.6 second longitudinal end
5.8 stiffening rib
8 a insulating device
8 b insulating device
8 c insulating device
11 a first inner hollow rail
11 b second inner hollow rail
12 insulating device
13 support rail
14 second inner hollow rail
15 second insulating device
16 support rail
17 support rail
19 PV module
20 first electric end
21 second electric end
22 inverter
24 first connection pole
25 second connection pole
26 mass potential
27 conventional support rail
28 a part of a string
29 connection of a PV module

The present invention is not limited to embodiments described herein; reference should be had to the appended claims.

What is claimed is:

1-27. (canceled)

28. A support rail for a row of PV modules, the support rail comprising:
an outer hollow rail;
a first inner hollow rail comprising a metal, and
an insulating device configured to electrically separate the outer hollow rail from the first inner hollow rail,
wherein the first inner hollow rail is accommodated within the outer hollow rail via the insulating device and is held in all directions transversely to the support rail in a positive-locking manner within the outer hollow rail by the insulating device.

29. The support rail as recited in claim 28, wherein the outer hollow rail comprises an inner cross section, and at least one of:
the first inner hollow rail further comprises an outer cross section, the inner cross section of the outer hollow rail and the outer cross section of the first inner hollow rail being congruently matched, and
the outer cross section of the first inner hollow rail comprises an envelope polygon, the inner cross section of the outer hollow rail and the envelope polygon of the outer cross section being congruently matched.

30. The support rail as recited in claim 28, wherein the first inner hollow rail is arranged centrally within the outer hollow rail.

31. The support rail as recited in claim 28, wherein the insulating device is provided as a counter-form to the outer hollow rail and as a counter-form to the first inner hollow rail at least in sections.

32. The support rail as recited in claim 28, wherein the insulating device is provided as more than one part at least one of longitudinally and transversely to the support rail.

33. The support rail as recited in claim 28, wherein the insulating device is a hollow rail.

34. The support rail as recited in claim 28, wherein at least one of the outer hollow rail, the first inner hollow rail, and the insulating device have an extrudable basic shape.

35. The support rail as recited in claim 28, wherein the insulating device comprises spacing elements, an outer side and an inner side, wherein the spacing elements are arranged on at least one of the outer side and the inner side of the insulating device.

36. The support rail as recited in claim 28, wherein the outer hollow rail comprises an outer side which comprises a bearing surface and an undercut fastening channel,
wherein the undercut fastening channel is configured to divide the bearing surface, and
the PV modules are configured to rest on the bearing surface.

37. The support rail as recited in claim 28, wherein the outer hollow rail comprises an inner cross section, the first inner hollow rail further comprises an outer cross section, the insulating device comprises an outer cross section, and insulating device comprises an inner cross section, wherein at least one of the inner cross section of the outer hollow rail, the outer cross section of the first inner hollow rail, the outer cross section of the insulating device, and the inner cross section of the insulating device have a trapezoidal shape.

38. The support rail as recited in claim 28, wherein the outer hollow rail comprises an outer cross section, the first inner hollow rail further comprises an outer cross section, and the insulating device further comprises an outer cross section, wherein a four-sided envelope polygon of at least one of the outer cross section of the outer hollow rail, the outer cross section of the first inner hollow rail, and the outer cross section of the insulating device forms a trapezoid.

39. The support rail as recited in claim 28, wherein the outer hollow rail comprises a cross section having a trapezoidal form, a first parallel side of the trapezoidal form comprising fastening edges arranged so as to extend on each end of the first parallel side, and a second parallel side of the trapezoidal form comprising a bearing surface arranged via an undercut fastening channel.

40. The support rail as recited in claim 28, further comprising a second inner hollow rail comprising a metal,
wherein the insulating device is configured to electrically separate the outer hollow rail and the second inner hollow rail, and
the second inner hollow rail is arranged within the outer hollow rail via the insulating device and is held in all directions transversely to the support rail in a positive-locking manner within the outer hollow rail by the insulating device.

41. The support rail according as recited in claim 28, further comprising a second inner hollow rail comprising a metal and a second insulating device,
wherein the second insulating device is configured to electrically separate the first inner hollow rail and the second inner hollow rail, and
the second inner hollow rail is arranged within the first inner hollow rail via the second insulating device and is held in all directions transversely to the support rail in a positive-locking manner within the first inner hollow rail by the second insulating device.

42. The support rail as recited in claim 28, wherein
the first inner hollow rail further comprises a first longitudinal end,
the PV modules are integrated in a string of PV modules electrically connected in series, the string of PV modules comprising a first electric end, and
the string of PV modules at the first electric end are electrically connected with the first longitudinal end of the first inner hollow rail.

43. The support rail as recited in claim 42, wherein an inverter is provided, and wherein the string of PV modules further comprises a second electric end, and the second electric end is electrically connected with the inverter.

44. The support rail as recited in claim 42, wherein an inverter is provided, and wherein the first inner hollow rail further comprises a second longitudinal end, and the second longitudinal end is electrically connected with the inverter.

45. The support rail as recited in claim 42, wherein an inverter is provided comprising a first pole and a second pole, and wherein the string of PV modules further comprises a second electric end, the second electric end is electrically connected with the first pole of the inverter, and the second longitudinal end of the first inner hollow rail is electrically connected with the second pole of the inverter.

46. The support rail as recited in claim 42, wherein a mass potential such as an earth potential is provided, and wherein the outer hollow rail is electrically connected with the mass potential.

47. A method for manufacturing a support rail as recited in claim 28, the method comprising:
a) arranging the insulating device on an outer side of the first inner hollow rail; and inserting the first inner hollow rail together with the insulating device into the outer hollow rail, or
b) arranging the insulating device on an inner side of the outer hollow rail; and inserting the first inner hollow rail into the insulating device.
